(19) United States
(12) Patent Application Publication
(10) Pub. No.: US 2007/0279980 A1
(43) Pub. Date: Dec. 6, 2007

(54) READING METHOD OF A NON-VOLATILE ELECTRONIC DEVICE AND CORRESPONDING DEVICE

(75) Inventors: Stefan Schippers, Peschiera del Garda (IT); Daniele Vimercati, Besana in Brianza (IT); Efrem Bolandrina, Alzano Lombardo (IT)

Correspondence Address: SEED INTELLECTUAL PROPERTY LAW GROUP PLLC, 701 FIFTH AVENUE, SUITE 5400, SEATTLE, WA, 98104-7092, US

(73) Assignee: STMICROELECTRONICS S.R.L., Agrate Brianza (IT)

(21) Appl. No.: 11/753,368

(22) Filed: May 24, 2007

(30) Foreign Application Priority Data
May 26, 2006 (IT) MI2006A001037

(51) Int. Cl. G11C 16/06; G11C 16/04; G11C 11/34

(52) U.S. Cl. 365/185.2; 365/185.03

(57) ABSTRACT

The invention relates to a reading method of a non-volatile electronic device of the multilevel type, the device comprises at least one first and one second memory bank each of said memory banks comprises a plurality of transistor cells organized in a matrix with a plurality of rows or wordlines and a plurality of columns or bitlines, at least one of said transistor cells being a reference cell containing a reference value, said bitlines being connected to at least one group of sense amplifiers, which comprises in turn a reference terminal and at least one signal output.

A crossed electric connection is provided between the reference terminal of at least one group of sense amplifiers of the first memory bank to an output of a subgroup of sense amplifiers of the second memory bank, and vice versa, and the subgroup of sense amplifiers associated with a memory bank is used as a connection to said reference cell during the reading step of the other memory bank.

### BACKGROUND

1. Technical Field

The present disclosure relates to a method and device for reading a non-volatile electronic device and, more particularly, to a method and device for reading a non-volatile electronic device of the multilevel type.

2. Description of the Related Art

As is known, multilevel FLASH memories store at least two information bits per each FLASH cell and thus can be used for storing four different information contents. The correct re-reading of the stored content requires the accurate comparison of the absorbed current of the FLASH cell with a similar current supplied by three references represented by the same number of FLASH cells arranged at suitable voltage thresholds. The three different voltage thresholds identify four states in which the matrix cell can be found, thus coding the two information bits.

A first known technical solution for meeting the need of correctly reading the content of the memory cells consists in the parallel reading of the references of the matrix cells by using additional reference read amplifiers, so called sense amplifiers. This first solution has several drawbacks, in particular it is difficult to bring common reference lines through the whole memory circuit due to the parasitic capacitances that are formed.

Moreover, it would be very onerous in terms of circuit area to reach a high matching degree between the reference line paths and the read matrix. Each unevenness between the reference and matrix lines reduces the margin (or the distance) between matrix cells and the references, which can result in a reading error. When this margin becomes lower than the variability and the offsets introduced by the circuitry, there is a reading error.

A second approach instead provides the use of more memory banks and the association of the references with each memory bank. This solution is not exempt from drawbacks since the area occupied on the integrated circuit (chip) is greater for this approach. A greater area occupied on the chip results, however, in greater manufacturing costs and therefore it is preferable to minimize the overall area used.

There is a need for a reading method and a corresponding non-volatile memory device having such functional and structural features as to carry out, with the greatest precision, the reading of multilevel cells and allow, at the same time, a greater evenness between reference and matrix overcoming the limits and drawbacks of known devices.

### BRIEF SUMMARY

The present disclosure exploits the sense amplifiers of a bank of cells not in use during the reading step as references for the bank of cells subjected to the reading operation, thus eliminating the circuitry normally dedicated to the references. This approach automatically realizes also a matching between matrix cells and reference cells, thus eliminating the variability that decreases the reading precision.

In accordance with one embodiment of the present disclosure a device is provided that includes at least one first and one second memory bank, each memory bank having a plurality of transistor cells organized in a matrix with a plurality of rows or wordlines and a plurality of columns or bitlines, at least one of the transistor cells being a reference cell, ideally containing a reference value, the bitlines connected to at least one sense amplifier, which includes in turn a reference terminal and at least one signal output.

The disclosure also relates to a non-volatile memory electronic device of the multilevel type having at least one first and one second memory bank, each of the memory banks having a plurality of transistor cells organized in a matrix with a plurality of rows or wordlines and a plurality of columns or bitlines, at least one of the transistor cells of each bank being a reference cell, the bitlines connected to at least one group of sense amplifiers, which includes in turn a reference terminal and at least one output terminal.

The disclosure also relates to a memory device of the multilevel Flash EEPROM type and the following description is made with reference to this specific field of application for convenience of illustration only.

In accordance with another embodiment of the disclosure, a memory is provided that includes at least one coupling between a reference terminal of at least one group of sense amplifiers of a first memory bank and an output terminal of a subgroup of sense amplifiers of a second memory bank, and at least one coupling between a reference terminal of at least one group of sense amplifiers of a second memory bank and an output terminal of the at least one group of sense amplifiers of the first memory bank, with the subgroup of sense amplifiers associated with the second memory bank adapted as a connection between a reference cell during a reading step of the other memory bank.

In accordance with yet another embodiment of the present disclosure, a circuit is provided that includes a non-volatile memory electronic device having at least one first memory bank and at least one second memory bank, each of the at least one first and second memory banks including a plurality of transistor cells coupled to a plurality of bitlines, at least one of the transistor cells of each memory bank comprises a reference cell containing a reference value, the bitlines coupled to at least one group of sense amplifiers that include a first terminal, a reference terminal, and at least one output terminal; and at least one electric coupling between the reference terminal of at least one group of sense amplifiers of the first memory bank and an output terminal of a subgroup of sense amplifiers of the second memory bank, and at least one amplifier of the second memory bank and an output terminal of the group of sense amplifiers of the first memory bank.

### BRIEF DESCRIPTION OF THE SEVERAL VIEWS OF THE DRAWINGS

The characteristics and the advantages of the method and of the device according to the disclosure will be apparent from the following description of an embodiment thereof given by way of indicative and non limiting example with reference to the annexed drawings.

FIG. 1 schematically shows, in a diagram, the distribution of the values of the reference thresholds relative to the corresponding four different information states contained in a two-bit multilevel cell.

FIG. 2 schematically shows an embodiment of a memory device according to the present disclosure that includes two banks of memory cells and the connection of the output signal of a sense amplifier of a memory bank with the reference terminal of the other memory bank.

FIG. 3 schematically shows an embodiment of a memory device according to the present disclosure that includes two banks of memory cells further divided into sub-groups by using a bus for the connections of the references between the sense amplifiers of a reading bank and the sense amplifiers of the bank used as reference.

FIG. 4 schematically shows the structure of a sense amplifier incorporated in the devices of FIG. 2 and FIG. 3 and shows in detail the connection point of the output signal.

FIG. 5 shows the connection of the sense amplifiers in another embodiment of a memory device according to the present disclosure.

### DETAILED DESCRIPTION

With reference to these figures, the structure and the operation of the device according to the disclosed embodiments will be described in detail.

Multilevel FLASH memories store at least two information bits for each FLASH cell. The correct re-reading of the stored content requires the accurate comparison of the current of the FLASH cell with a similar current supplied by three references represented by the same number of FLASH cells arranged at suitable voltage thresholds.

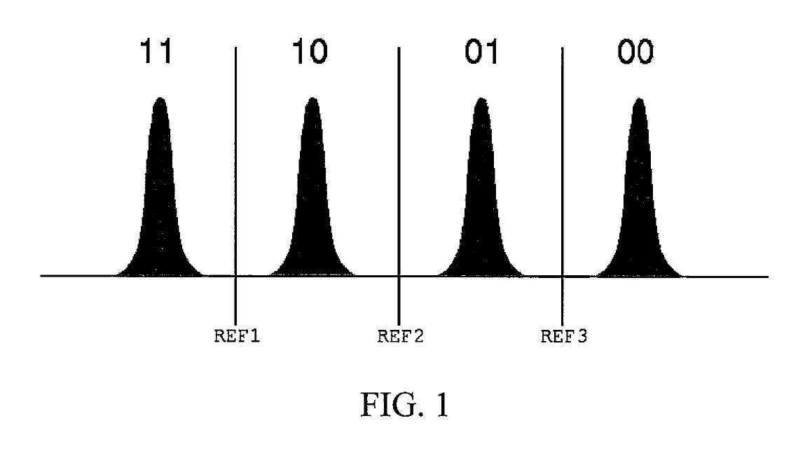

FIG. 1 shows an arrangement with at least three references REF1, REF2 and REF3; the horizontal axis represents a threshold voltage Vth of the cells.

The three different voltage thresholds Vth identify in fact the four states in which the matrix cell can be found, then coding the above two information bits.

In the case of FIG. 1, the logic value 11 is associated with a cell that is crossed by a current when the Vth applied to the gate terminal is lower than the value REF1. Similarly, for cells with logic value 10 reference is made to cells conducting with a Vth applied to the gate terminal of intermediate value between REF1 and REF2; for the cells with the logic value 01 reference is made to cells conducting with a Vth between REF2 and REF3 and for the cells with the logic value 00 reference is made to cells conducting when the value Vth applied to the gate terminal is higher than REF3.

For carrying out, with the highest precision, the multilevel reading it is necessary to pay particular attention to the dynamic effects of the reading and to the equalization (matching) of the reading paths of the matrix and the reference.

Each unevenness or difference between the reference and the matrix values results in a reading error that reduces the difference between matrix cells and references. When this margin becomes greater than the variability and the offsets introduced by the circuitry, there is a reading error.

Another element to be taken into consideration in the realization of a flash memory is the area occupied by the circuitry for the references. Generally, small matrixes of reference cells, of sense amplifiers, and of other necessary components are preferred. As already said, the overall area must be kept at the minimum for matters of cost.

Advantageously, according to the present disclosure, both the requisites of matching and area can be well solved by using, for the reading of a memory bank, three references that are read by means of corresponding sub-groups or arrays of sense amplifiers of the other bank that is not involved in the reading step.

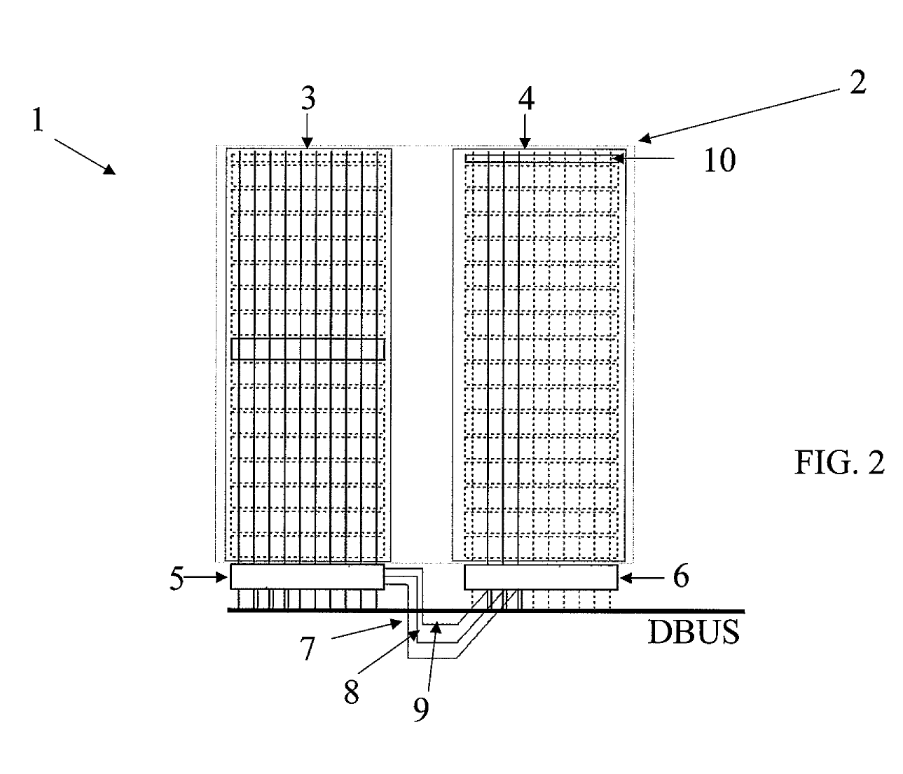

FIG. 2 schematically shows a non-volatile memory electronic device monolithically integrated on a semiconductor substrate that implements this approach. In the embodiment here described and shown in FIG. 2, by way of an indicative and non-limiting example, the device includes a matrix 2 of non-volatile memory cells formed by transistors of the MOS type. The cells are organized in rows or word lines and columns or bit lines.

The matrix 2 includes two distinct banks, 3 and 4, of memory cells. Nothing obviously forbids the organization of the device with a plurality of banks. The columns of each bank 3, 4 refer to respective groups or arrays of sense amplifiers 5, 6 that have the respective outputs connected to a data bus DBUS.

A small sector 10 of each bank 3, 4 is used for housing the reference cells; as it will be seen hereafter for this small sector 10, an array corresponding to a single word line of a matrix bank is enough.

Each group 5, 6 of sense amplifiers shows a first input connected to a column of a matrix bank and a second input connected to a first potential reference. In the case of multilevel memories, further inputs connected to further potential references are added. In the example of a multilevel memory with two bits per cell, there is a total of three potential references. Each group of sense amplifiers 5, 6 then has a first input connected to a column of a matrix bank, a second input connected to a first potential reference, a third input connected to a second potential reference and a fourth input connected to a third potential reference.

According to the embodiment here described, these potential references are supplied by a memory bank not in use. In FIG. 2, only the memory bank 3 is in the reading phase while the memory bank 4 is used for supplying the three references.

For this aim a connection 7 is provided between the output of a first sub-group of sense amplifiers of the bank 4 and between the second input of the sense amplifiers of the bank 3. In this way the output of the sub-group of sense amplifiers of the bank 4 is used as a potential reference for the sense amplifiers of the bank 3. In the case as per the embodiment of a multilevel memory cell with two bits per cell it is necessary to arrange three potential levels. In a similar way, a connection 8 is thus provided between the output signal of at least one second sub-group of sense amplifiers of the bank 4 and between the third input of the sense amplifiers of the bank 3 and a connection 9 between a third sense amplifier of the bank 4 and between the fourth input of the sense amplifiers of the bank 3.

This configuration ensures a perfect ‘matching’ of matrix/reference reading; also the wordline of the small sector 10 of the references has been chosen with the same length of the matrix sectors of the banks 3 and 4, although only three groups of sense amplifiers are necessary (and thus a very narrow horizontal portion of array) for reading the references; this measure makes it identical also the dynamic response of the matrix and reference wordline.

Once the wordline corresponding to the small sector 10 containing the reference cells has been raised, the above connections 7, 8, 9 are supplied by the respective sense amplifiers of the bank 4, which thus bring back the potential references. At this point it is possible to carry out a reading on the bank 3.

It is to be observed that the situation indicated in FIG. 2 can be applied in the same way in case of reading of the bank 4; in this case the reading out of the references through the bank 3 will be carried. It is obviously necessary to provide further connections between the output signal of the three sense amplifiers of the bank 3 and the inputs of the potential references of the sense amplifiers of the bank 4. These connections are not shown in FIG. 2.

Another proper observation to be made is that the three sense amplifiers used also as a reference are not necessarily those at the ends, for avoiding unevenness due to edge effects.

The small sector 10 with the reference cells is part of the memory matrix 2. It is suitable to have a logic of the memory device that makes this small sector 10 only accessible through reading and non modifiable by the user of the device. Advantageously, this small sector 10 is programmed during the manufacturing of the memory device with the suitable values.

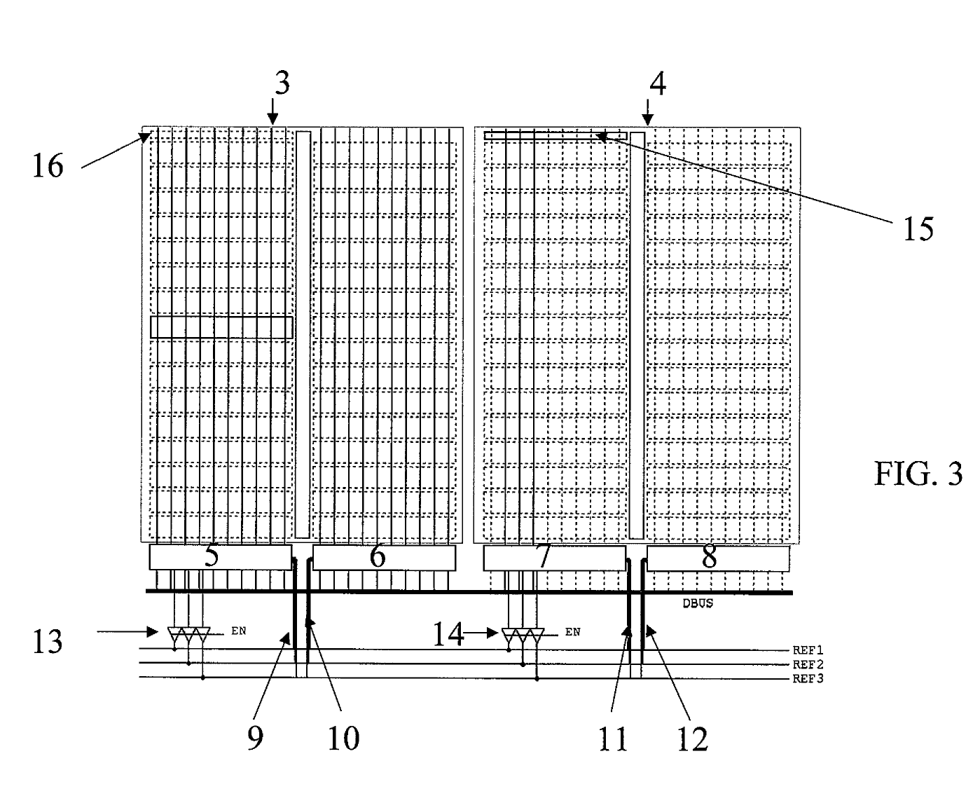

For several reasons, which can be for example of technical nature or related to manufacturing difficulties, but are often more simply due to manufacturing specifications, often, a memory bank of a non-volatile electronic device is further divided. This case is shown in FIG. 3. Here, each single sense amplifier, 5, 6, 7, 8, manages a plurality of bitlines, and thus in the example here described the objects 5, 6, 7, 8 of FIG. 3 comprise four groups or arrays of sense amplifiers with a multiplexing logic for the number of bitlines.

Each group or subgroup of sense amplifiers should be equipped with connections with the potential references REF1, REF2, REF3 and thus, having a plurality of sense amplifiers and of memory banks, the number of necessary connections increases significantly.

In order to avoid a plurality of these connections, in FIG. 3 a bus RFBUS for the potential references is used.

The inputs of the references of each sense amplifier 5, 6, 7 and 8 are connected to said bus RFBUS for the potential references through the connections 9, 10, 11 and 12. The outputs of the three groups of sense amplifiers corresponding to the bitlines connected to the cells containing the reference values of the small reference sectors 15 or 16 are provided with means EN for the connection to said bus RFBUS for the potential references. Said means EN carry out a connection to the bus only when the references contained in the small sector of the memory bank at issue are used. For example, as shown in FIG. 3, during the reading of the memory bank 3, the connections EN 14 are activated, while the connections EN 13 remain deactivated. All the sense amplifiers 5, 6, 7, 8. however, maintain the connection 9, 10, 11, 12 of the inputs for the potential references of the bus RFBUS.

At this point it is suitable to deepen some details of the operation of a sense amplifier, since not in all microchip architectures is it possible to use the normal output of a sense amplifier for the connection of the potential references to the bus.

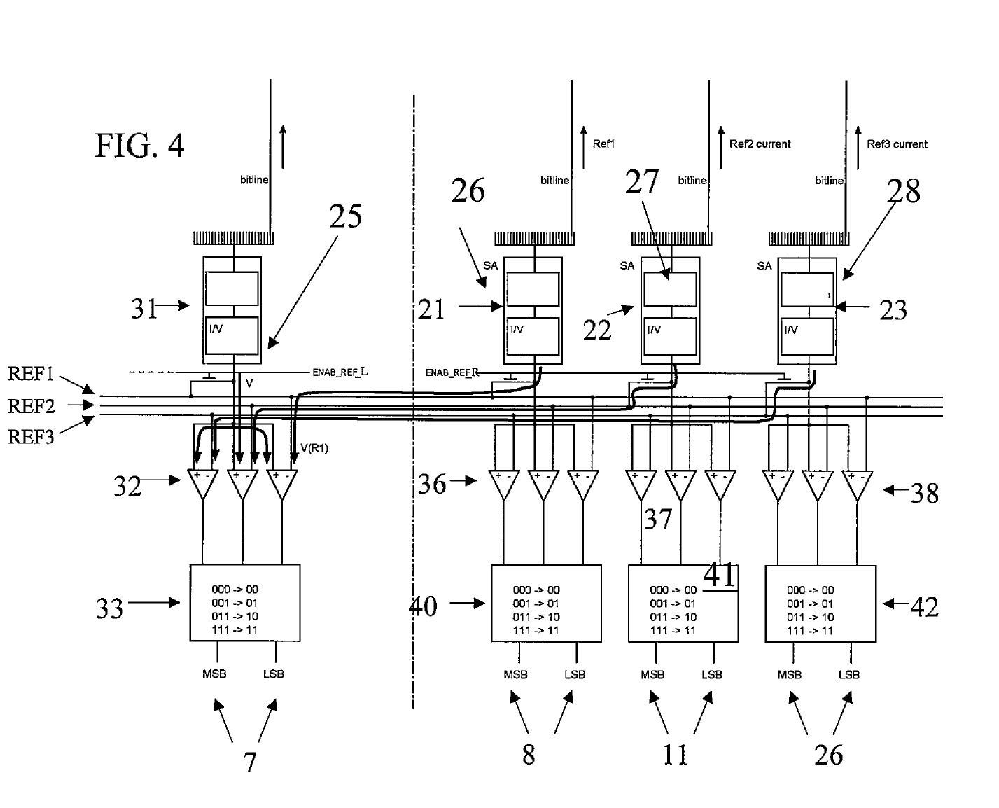

In particular, FIG. 4 shows four sense amplifiers 25, 26, 27 and 28 with the respective connections to each other. A sense amplifier is normally an electronic device connected to the bitline of a memory matrix intended for carrying out a comparison between a memory cell and a reference cell. In a multilevel architecture with two bits per cell, the output has two digital lines, indicated with MSB and LSB, for indicating the state of the multilevel cell.

A sense amplifier normally includes a plurality of components for giving a digital value to the current of the cell connected to the bitline. In FIG. 4 the sense amplifier 25 includes a first input stage 31 and a second output stage 32, which outputs the digital values reported in the block 33.

The other three sense amplifiers 26, 27 and 28 of FIG. 4 comprise similar components indicated with the numbers 21, 22 and 23, as input stages, associated with respective output stages 36, 37 and 38. The blocks 40, 41 and 42 respectively indicate the values of the outputs of the stages 36, 37 and 38.

In a multilevel reading architecture the first input stage 31 of the sense amplifier maintains the bitline at a suitable reading voltage (about 0.8 Volt) and produces a voltage proportional to the current consumed by the flash cell under test, i.e., it operates as converter I/V.

The output of this first stage 31 is thus a voltage that is proportional to the current consumed by the flash cell. This voltage is then compared by a second stage 32 with the three voltages generated in a similar way by the three references. As shown in FIG. 4, the result of the comparison issues at the outputs the values reported in the block 33. Through a signal ENABLE_REF_R the output voltage of the input stages 21, 22 and 23 can be connected to a line of a bidirectional bus with three wires, REF1, REF2, REF3.

The signals ENABLE_REF_R and ENABLE_REF_L thus change the state of the sense amplifier, forcing from a use for the sole reading to a use for supplying a reference voltage.

Three groups of sense amplifiers of a given bank 3, 4 can operate also as reference and transmit the reading voltage on said bidirectional bus with three wires. It is obvious that if the sense amplifiers of the right bank drive the bus while the sense amplifiers of the left bank will be disconnected and vice versa.

As it is then seen in FIG. 4 the connection of the reference signals is upstream of the digital portion. The signals flowing on the bidirectional bus with three wires are in fact analogue signals, and, i.e., the three voltages that are proportional respectively to the reference cells.

The block 33 downstream of the sense amplifier in reading on the left finally attends to the decoding of the result of the comparison from the output of the second stage 32 with the three reference currents two-bit digital information (00, 01, 10, 11) are obtained on the two digital lines MSB and LSB.

This architecture is suitable for a non-ramp reading mode. In the reading mode described in FIG. 4 a fix and constant voltage is applied to the wordline of all the cells which are in reading.

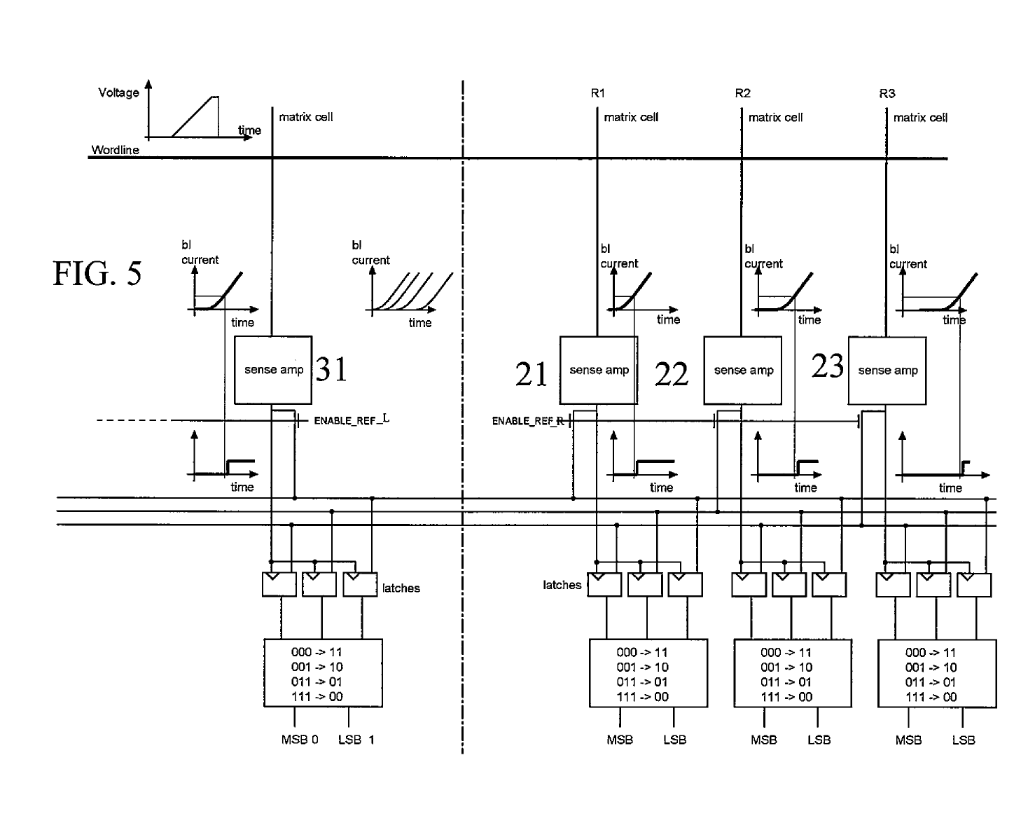

Instead, in the case of a ramp reading the scheme of FIG. 5 is applied.

For this reading mode instead of applying a constant voltage, an increasing voltage is applied, which increases in a linear way with the time, thus starting from 0V and reaching the highest voltage (5V . . . 7V, depending on the process) in a very reduced time (about 40/50 ns).

When a flash cell is subjected to a gate voltage being variable and linearly increasing, what occurs is that as long as the wordline voltage is lower than the threshold voltage of the flash cell (i.e., the voltage at which it enters in conduction and consumes current) no current is observed on the bitline. As soon as the voltage exceeds the threshold then an increasing current is observed on the bitline.

FIG. 5 shows how the method of the present disclosure can be applied to the ramp reading case. In this case on the bidirectional bus of the three potential references REF1, REF2, and REF3 no analog signals flow, but digital signals, which switch from 0 to 1 when the cell exceeds a predetermined current (for instance 7 uA). In this type of reading the task of the sense amplifier is simply that of indicating by means of a digital output the time instant in which the current of the cell exceeds a value that has been fixed a priori by the sense amplifier.

In the case of a reading with ramp mode on the bidirectional bus with three wires, only one-bit digital signals flow, and according to the time instant of a one-bit digital signal, the reference voltage associated therewith is established.

In conclusion, the device according to the embodiments described herein allows the reading of the memory cells without additional circuitry for the references and results to be matched with the structure of the matrix, in particular same bitline, same sense amplifier, same distances, and circuit topology.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet, are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of reading a non-volatile electronic device of the multilevel type, the device including at least one first and one second memory bank, each of the memory banks having a plurality of transistor cells organized in a matrix with a plurality of rows or wordlines and a plurality of columns or bitlines, at least one of the transistor cells configured as a reference cell containing a reference value, the bitlines connected to at least one group of sense amplifiers having a first terminal, a reference terminal, and at least one signal output, the method comprising:
a. providing an electric connection between the reference terminal of at least one group of sense amplifiers of the first memory bank to an output of a subgroup of sense amplifiers of the second memory bank, and vice versa;
b. enabling the group of sense amplifiers associated with the first memory bank of a cell to be read;
c. enabling at the same time the subgroup of sense amplifiers of the second memory bank to serve as a connection to the reference cell;
d. carrying out the reading of the content of at least one portion of the first memory bank through the group of sense amplifiers associated with the memory bank to be read and using the other subgroup of sense amplifiers for the reading of the values of the potential references on the reference terminal of the at least one group of sense amplifiers of the first memory bank.

2. The method of claim 1, comprising the following step:
storing the values of the potential references in at least one small memory sector with a privilege of writing different from the other memory cells and accessible by the user only in reading.

3. A non-volatile memory electronic device of the multilevel type, comprising at least one first and one second memory bank, each of said memory banks comprising a plurality of transistor cells organized in a matrix with a plurality of rows or wordlines and a plurality of columns or bitlines, at least one of said transistor cells of each memory bank comprising a reference cell containing a reference value, said bitlines connected to at least one group of sense amplifiers that include a first terminal, a reference terminal, and at least one output terminal,
at least one connection between a reference terminal of said at least one group of sense amplifiers of said first memory bank and an output terminal of a subgroup of sense amplifiers of said second memory bank, and at least one connection between the reference terminal of said at least one group of sense amplifiers of said second memory bank and an output terminal of the group of sense amplifiers of said first memory bank, the subgroup of sense amplifiers associated with the second memory bank being used as a connection to said reference cell during the reading step of the other memory bank.

4. The memory device of claim 3, wherein said reference terminals of said groups of sense amplifiers are connected to a bus of reference lines, and means for selectively connecting said terminals to said bus of the reference lines.

5. The memory device of claim 3, wherein the bitlines corresponding to the cells containing a potential reference value are those that are far from the ends of the memory bank.

6. The memory device of claim 3, wherein the cells containing said reference values belong to a sector of the memory equipped with a writing privilege different from other memory cells.

7. The memory device of claim 6, wherein the cells containing said reference values belong to a sector of the memory accessible by the user only in reading.

8. The memory device of claim 1, wherein said memory cells are of the multilevel type with 2 bits per cell.

9. A memory, comprising:
at least one coupling between a reference terminal of at least one group of sense amplifiers of a first memory bank and an output terminal of a subgroup of sense amplifiers of a second memory bank, and at least one coupling between a reference terminal of at least one group of sense amplifiers of a second memory bank and an output terminal of the at least one group of sense amplifiers of the first memory bank, with the subgroup of sense amplifiers associated with the second memory bank adapted as a connection between a reference cell during a reading step of the other memory bank.

10. The memory of claim 9, wherein each reference terminal is coupled to a bus of reference lines by a connection circuit.

11. The memory of claim 9, wherein the first and second memory banks have writing privileges, and the reference values are stored in reference cells containing a writing privilege different from other memory cells in the memory bank.

12. An electronic circuit, comprising:
a non-volatile memory electronic device having at least one first memory bank and at least one second memory bank, each of the at least one first and second memory banks comprising a plurality of transistor cells coupled to a plurality of bitlines, at least one of the transistor cells of each memory bank comprises a reference cell containing a reference value, the bitlines coupled to at least one group of sense amplifiers that include a first terminal, a reference terminal, and at least one output terminal; and
at least one electric coupling between the reference terminal of at least one group of sense amplifiers of the first memory bank and an output terminal of a subgroup of sense amplifiers of the second memory bank, and at least one amplifier of the second memory bank and an output terminal of the group of sense amplifiers of the first memory bank.

13. The circuit of claim 12, comprising a bus of reference lines coupled to each reference terminal.

14. The circuit of claim 13, comprising devices for selectively coupling the reference terminals to the bus of reference lines.

15. The circuit of claim 12, wherein the reference cells containing the reference values are associated with a sector of their respective memory bank that is adapted to have a writing privilege that is different from a writing privilege of other memory cells in the respective memory bank.

16. The circuit of claim 12, wherein the electric coupling comprises a crossed electric coupling.
